(19) United States
(12) Patent Application Publication
(10) Pub. No.: US 2026/0165155 A1
(43) Pub. Date: Jun. 11, 2026

(54) SEMICONDUCTOR DEVICE

(71) Applicant: Mitsubishi Electric Corporation, Tokyo (JP)

(72) Inventors: Yuya OMAGARI, Tokyo (JP); Yuki TERADO, Tokyo (JP)

(73) Assignee: Mitsubishi Electric Corporation, Tokyo (JP)

(21) Appl. No.: 19/342,267

(22) Filed: Sep. 26, 2025

(30) Foreign Application Priority Data
Dec. 11, 2024 (JP) 2024-216950

(51) Int. Cl. H01L 23/495; H01L 21/48; H01L 23/00; H01L 25/065

(52) U.S. Cl. CPC H10W 70/429; H10W 70/048; H10W 90/00; H10W 90/811; H10W 72/07552; H10W 72/527; H10W 90/753; H10W 90/755

(57) ABSTRACT

A semiconductor device includes a package having a first side and a second side opposite the first side, a conductor layer having a first region and a second region between the first region and the second side, a semiconductor chip on the first region; a control chip on the second region, a power terminal on the first side and connected to the semiconductor chip, a control terminal on the second side and connected to the control chip, and a suspension lead extending from a position on an outer periphery of the package closer to the first side than the first region to the second region, wherein a first step portion is formed in the suspension lead such that a portion connected to the second region is lower than a portion provided in the outer periphery and the second region is lower than the control terminal.

### BACKGROUND

### Field

The present disclosure relates to a semiconductor device.

### Background

JP 2006-332573 A discloses a package structure for a power module. The package structure includes a power chip and a lead frame. A circuit board is connected to a portion of the lead frame. A control chip is mounted on the circuit board.

In JP 2006-332573 A, a pin connected to the power chip is provided on one side of the package, and a pin connected to the control chip is provided on the other side of the package. Each pin has a step inside the package. This allows the power chip and the like to be arranged on a heat dissipation surface side. However, in such a structure, when the lead frame is bent to form the steps on the pins on both sides of the package, there is a risk that extra space will be created within the package.

### SUMMARY

The present disclosure has been made to solve the above-mentioned problems, and aims to provide a semiconductor device that can reduce the space inside the package.

The features and advantages of the present disclosure may be summarized as follows.

According to an aspect of the present disclosure, a semiconductor device includes a package having a first side and a second side opposite the first side; a conductor layer having a first region provided inside the package and a second region provided inside the package between the first region and the second side; a semiconductor chip provided on the first region; a control chip provided on the second region and configured to control the semiconductor chip; a power terminal provided on the first side of the package and electrically connected to the semiconductor chip; a control terminal provided on the second side of the package and electrically connected to the control chip; and a suspension lead extending from a position on an outer periphery of the package closer to the first side than the first region to the second region; wherein a first step portion is formed in the suspension lead such that a portion connected to the second region is lower than a portion provided in the outer periphery; and the second region is provided at a position lower than a portion of the control terminal that is provided inside the package.

Other and further objects, features and advantages of the disclosure will appear more fully from the following description.

### BRIEF DESCRIPTION OF DRAWINGS

FIG. 1 is a plan view of a semiconductor device according to a first embodiment.

FIG. 2 is a cross-sectional view of the semiconductor device according to the first embodiment.

FIG. 3 is a plan view of a semiconductor device according to a first comparative example.

FIG. 4 is a diagram illustrating a method for forming a step portion according to a second comparative example.

FIG. 5 is a diagram illustrating a method for forming a step portion according to the first embodiment.

FIG. 6 is a cross-sectional view of a semiconductor device according to a second embodiment.

FIG. 7 is a plan view of a semiconductor device according to a fourth embodiment.

### DESCRIPTION OF EMBODIMENTS

Semiconductor devices according to the respective embodiments will be described with reference to the drawings. The same or corresponding components are denoted by the same reference numerals, and repeated description may be omitted.

### First Embodiment

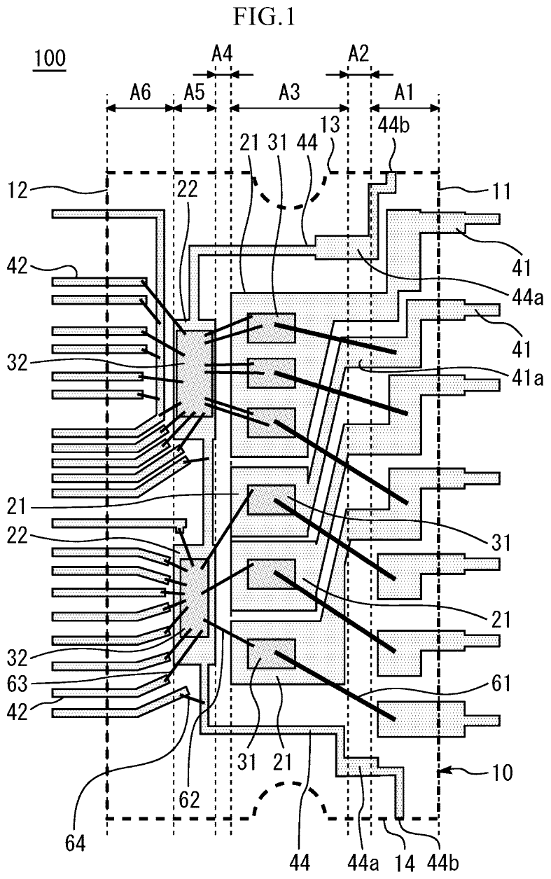

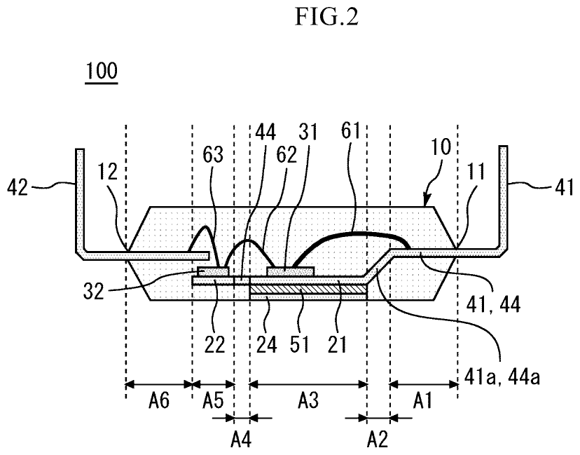

FIG. 1 is a plan view of a semiconductor device 100 according to a first embodiment. FIG. 2 is a cross-sectional view of the semiconductor device 100 according to the first embodiment. The semiconductor device 100 includes a package 10. The package 10 is formed of, for example, a sealing resin. The package 10 has a first side 11, a second side 12 opposite to the first side 11, and a third side 13 and a fourth side 14 between the first side 11 and the second side 12.

A conductor layer having a first region 21 and a second region 22 is provided inside the package 10. The first region 21 and the second region 22 are, for example, metal plates provided separately and can be made of copper. The second region 22 is provided between the first region 21 and the second side 12. A semiconductor chip 31 is provided on the first region 21. A control chip 32 configured to control the semiconductor chip 31 is provided on the second region 22. That is, the first region 21 is a power-side die pad, and the second region 22 is a control-side die pad. The first region 21 and the second region 22 may be circuit patterns.

In the example of FIG. 1, six semiconductor chips 31 are mounted in four first regions 21. The semiconductor chip 31 is, for example, a power chip. The number of first regions 21 that the package 10 has is not limited. Furthermore, the number and types of semiconductor chips 31 housed in the package 10 are not limited. Furthermore, the number of semiconductor chips 31 provided in one first region 21 is not limited.

In the example of FIG. 1, two second areas 22 are provided, and one control chip 32 is mounted in each second area 22. The control chip 32 may be an IC chip. The number of second regions 22 that the package 10 has is not limited. Furthermore, the number of control chips 32 provided in one second area 22 is not limited.

A power terminal 41 electrically connected to the semiconductor chip 31 is provided on the first side 11 of the package 10. Some of the multiple power terminals 41 and the semiconductor chips 31 are electrically connected by power wires 61. Some of the multiple power terminals 41 are directly connected to the first regions 21. A control terminal 42 electrically connected to the control chip 32 is provided on the second side 12 of the package 10. The multiple control terminals 42 and the control chip 32 are electrically connected by control wires 63. The semiconductor chips 31 and the control chips 32 are electrically connected by wires 62.

The semiconductor device 100 includes a suspension lead 44 that extends from a position on an outer periphery of the package 10 closer to the first side 11 than the first region 21 to the second region 22. Each terminal, die pad and suspension lead 44 shown in FIGS. 1 and 2 are provided as part of a lead frame. Before the outer frame (not shown) of the lead frame is cut, each terminal is supported by the outer frame of the lead frame. The suspension leads 44 have the function of fixing the second region 22 to the outer frame of the lead frame. In this embodiment, a pair of suspension leads 44 are provided on both sides of the package 10. This allows the two second regions 22 to be supported. The number and arrangement of the suspension leads 44 can be changed as appropriate.

As shown in FIG. 2, the multiple power terminal 41 has a step portion 41a formed inside the package 10. As a result, the first region 21 is disposed at a position lower than the portion of the power terminal 41 that is provided at the end of the package 10. An insulating layer 51, which is an insulating sheet or an insulating substrate, is provided directly below the first region 21 inside the package 10. A conductor layer 24 is provided below the insulating layer 51. The bottom surface of the package 10 serves as a heat dissipation surface. Therefore, by placing the first region 21 closer to the heat dissipation surface, the heat dissipation performance of the semiconductor chip 31 can be improved. In the cross-sectional view shown in FIG. 2, the power terminals 41 overlap each other.

The multiple control terminals 42 may not have a step inside the package 10. In other words, the multiple control terminals 42 may extend horizontally inside the package 10. In the cross-sectional view shown in FIG. 2, the multiple control terminals 42 overlap each other. In this embodiment, only the sealing resin is provided directly below the second region 22 inside the package 10. The configuration directly below the first region 21 and the second region 22 can be changed as appropriate.

For the sake of explanation, the area from the first side 11 of the package 10 to the step portion 41a is referred to as an area A1. In the area A1, the power terminals 41 are provided horizontally. The portion of the package 10 where the step portion 41a of the power terminal 41 is provided is designated as an area A2. The portion of the package 10 where the first region 21 is provided is referred to as a region A3. In the package 10, the portion between the first region 21 and the second region 22 is referred to as a region A4. The portion of the package 10 where the second region 22 is provided is referred to as a region A5. The portion from the second side 12 of the package 10 to the second region 22 is defined as a region A6.

The suspension lead 44 has a step portion 44a formed therein so that the portion connected to the second region 22 is lower than the portion provided on the outer periphery of the package 10. As a result, the second region 22 is located at a lower position than the portion of the control terminal 42 that is located inside the package 10. In the direction from the first side 11 toward the second side 12, the step portion 44a and the step portion 41a are formed at the same position. That is, the step portion 44a and the step portion 41a are both formed in the region A2.

That is, the multiple power terminals 41 and the multiple suspension leads 44 provided on the first side 11 side of the package 10 are uniformly bent at the same position in the direction along the third side 13. Therefore, in the cross-sectional view shown in FIG. 2, the multiple power terminals 41 and the multiple suspension leads 44 overlap each other. Moreover, the first region 21 and the second region 22 are provided at the same height.

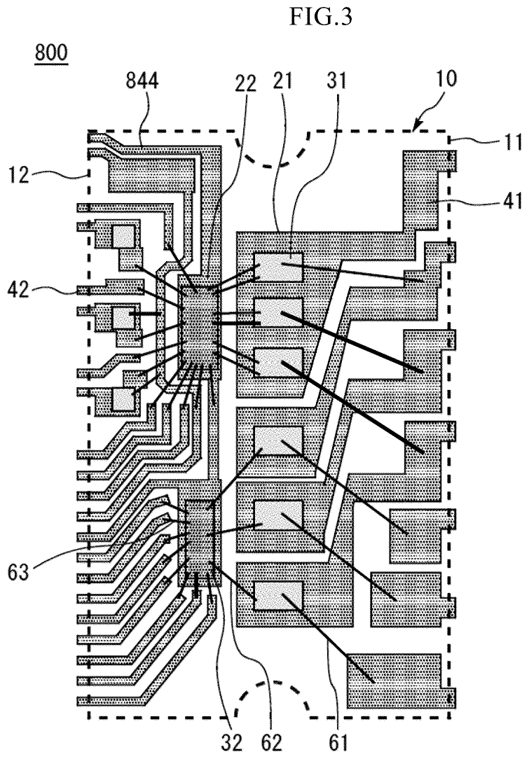

Next, the effects of this embodiment will be described. FIG. 3 is a plan view of a semiconductor device 800 according to a first comparative example. In the semiconductor device 800 according to the first comparative example, a suspension lead 844 for fixing the second region 22 to the outer frame of the lead frame is provided on the second side 12 side. Furthermore, the control terminal 42 and the suspension lead 844 do not have a step portion.

In semiconductor power modules, as ICs (Integrated Circuits) become more multifunctional, it is expected that the influence of temperature rise caused by control chips will become greater. However, in the semiconductor device 800 according to the comparative example, the control terminal 42 and the suspension lead 844 do not have a step portion, so the second region 22 is at the same height as the control terminal 42. Therefore, the distance from the control chip 32 to the heat dissipation surface is long, which may make it difficult to ensure heat dissipation. In contrast to this, according to this embodiment, the step portion 44a allows the second region 22 to be closer to the heat dissipation surface. Therefore, the heat dissipation performance of the control chip 32 can be improved.

Furthermore, in this embodiment, the step portion 44a is formed on the suspension lead 44 extending from the first side 11 side. Therefore, in order to arrange the second region 22 at a lower position within the package 10, it is not necessary to bend the leads on the second side 12 side inside the package 10. Therefore, the space inside the package 10 can be reduced.

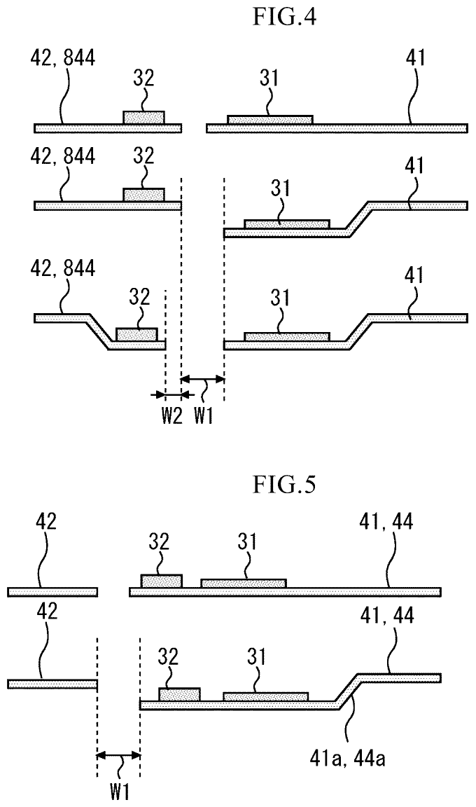

This will be explained with reference to FIGS. 4 and 5. FIG. 4 is a diagram illustrating a method for forming a step portion according to a second comparative example. The power terminals 41, the control terminals 42, the suspension leads 844, the first regions 21 and the second regions 22 of the comparative example are formed by bending one lead frame. FIG. 4 shows, from above, a state before bending, a state in which only the power terminals 41 are bent, and a state in which the power terminals 41, the control terminals 42, and the suspension leads 844 are bent. The state in which only the power terminal 41 is bent corresponds to the first comparative example. The distance between the power terminal 41 and the control terminal 42 when only the power terminal 41 is bent is defined as W1. By further bending the control terminal 42 and the suspension lead 844, the distance between the power terminal 41 and the control terminal 42 is widened to W1+W2. In other words, bending the suspension leads 844 improves the heat dissipation of the control chip 32, but widens the gaps within the package 10.

FIG. 5 is a diagram illustrating a method for forming the step portion according to the first embodiment. The power terminals 41, the control terminals 42, the first regions 21, the second regions 22 and the suspension leads 44 of this embodiment are also formed by bending one lead frame. In FIG. 5, the power terminal 41 and the suspension lead 44 overlap each other. In this embodiment, the control chip 32 can be disposed below by bending the suspension lead 44. Therefore, there is no need to bend the control terminal 42, and the distance between the power terminal 41 and the control terminal 42 is W1. Therefore, the heat dissipation performance of the control chip 32 can be improved while reducing the space inside the package 10.

Furthermore, since the distance between the power terminal 41 and the control terminal 42 can be reduced, the semiconductor chip 31 and the control chip 32 can be arranged close to each other. This makes it possible to improve the temperature detection sensitivity when, for example, the control chip 32 has a built-in function of monitoring the temperature of the semiconductor chip 31.

Furthermore, the wires connected to the control chip 32 may be swept away by the injection pressure of the resin during resin injection and may fall over. This may cause the wire to come into contact with a different electrode, resulting in a defect. In particular, if the distance between the power terminal 41 and the control terminal 42 is wide, the span of the wire 62, which is the direct wire connecting the control chip 32 and the semiconductor chip 31, becomes long and the wire 62 is easily affected by the flow of resin. In this embodiment, the power terminal 41 and the control terminal 42 can be placed close to each other, and the span of the wire 62 can be shortened. Therefore, it is possible to prevent the wire 62 from coming into contact with a different electrode and causing a short circuit.

Furthermore, by providing only the sealing resin directly below the first region 21, it is possible to suppress noise leakage.

As a modification of this embodiment, the step portion 44a and the step portion 41a may be formed at different positions in the direction from the first side 11 toward the second side 12. The effect of this embodiment can be obtained if the step portion 44a is provided at any position on the suspension lead 44. For example, the step portion 44a may be formed at any position closer to the first side 11 than the first region 21. The heights of the first region 21 and the second region 22 may be different. Furthermore, an end 44b of the suspension lead 44 is not limited to being provided on the third side 13 or the fourth side 14, but may also be provided on the first side 11.

As shown in FIG. 2, the diameter of the control wire 63 connecting the control chip 32 and the control terminal 42 may be smaller than the diameter of the power wire 61 connecting the semiconductor chip 31 and the power terminal 41. The metal lines connected to the control chip 32 generally do not carry high currents. Therefore, the diameter of the control wire 63 can be made smaller. This allows the pads connecting the control chip 32 and the control wires 63 to be made smaller. Therefore, the control chip 32 can be made smaller. The diameter of the wire 62 may be smaller than the diameter of the power wire 61.

The control chip 32 may be provided with a bootstrap diode (BSD) or a regulator. In this embodiment, the heat dissipation of the control chip 32 can be improved, so that a BSD or a regulator that consumes a large amount of power can be built into the control chip 32. This allows the package 10 to be made smaller. Moreover, the degree of freedom in frame layout can be improved.

The suspension lead 44 may be connected to one of the control terminals 42 by wire 64. The rear surface of the control chip 32 is, for example, a GND electrode. That is, the second region 22 becomes GND. By connecting the suspension lead 44 and the control terminal 42 with the wire 64, the control terminal 42 can be used as a GND terminal. The suspension lead 44 may also be used as a terminal such as a GND terminal.

In the example of FIG. 1, the outer peripheral end 44b of the suspension lead 44 is covered with a sealing resin. Of the end 44b of the suspension leads 44, a cut surface formed when the lead frame is cut may be exposed from the sealing resin. When the suspension lead 44 is used as a terminal, the end 44b should be protruded from the sealing resin.

The semiconductor chip 31 may be made with a wide bandgap semiconductor. The wide bandgap semiconductor is, for example, silicon carbide, gallium nitride-based material, or diamond.

The above-described modifications can be applied as appropriate to the semiconductor devices according to the following embodiments. The semiconductor devices according to the following embodiments have many points in common with the first embodiment, so the following description will focus on the differences from the first embodiment.

### Second Embodiment

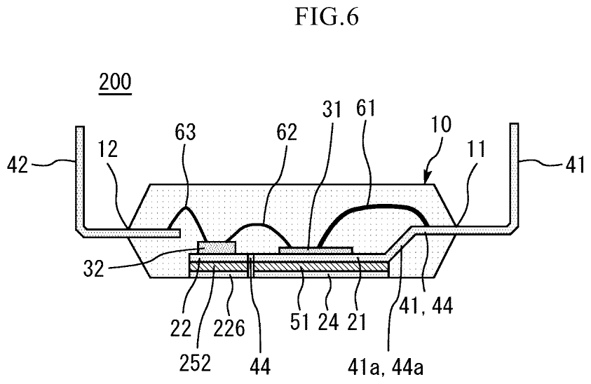

FIG. 6 is a cross-sectional view of a semiconductor device 200 according to the second embodiment. This embodiment differs from the first embodiment in that insulating layers 51 and 252, which are insulating sheets or insulating substrates, are provided directly below the first region 21 and the second region 22. The other configurations are the same as those of the first embodiment. A conductor layer 226 is provided below the insulating layer 252. A DBC (Direct Bonded Copper) structure may be provided below the semiconductor chip 31 and the control chip 32. The DBC structure is a structure in which an insulating substrate made of ceramic or the like is provided between copper layers.

In this embodiment, by providing an insulating sheet or insulating substrate having a higher thermal conductivity than the sealing material between the control chip 32 and the heat dissipation surface, it is possible to further improve heat dissipation. Furthermore, by making the first region 21 and the second region 22 the same height, the same type of material can be used for the insulating layers 51 and 252. In this embodiment, the heights of the first region 21 and the second region 22 may also be different.

### Third Embodiment

In this embodiment, the dielectric constant of the material directly below the control chip 32 is lower than the dielectric constant of the material directly below the semiconductor chip 31. The other configurations are the same as those of the first or second embodiment. For example, the dielectric constant of the insulating layer 252 in the second embodiment is set lower than the dielectric constant of the insulating layer 51.

If the control chip 32 is located close to the heat dissipation surface, noise generated in the semiconductor chip 31 may leak in from the heat dissipation surface, causing the control chip 32 to malfunction. The dielectric constant of the material directly below the control chip 32 is lower than the dielectric constant of the material directly below the semiconductor chip 31, so that noise can be suppressed from leaking in. In the configuration of the first embodiment, too, by using a sealing material having a lower dielectric constant than the insulating layer 51 directly below the semiconductor chip 31, it is possible to suppress noise leakage.

### Fourth Embodiment

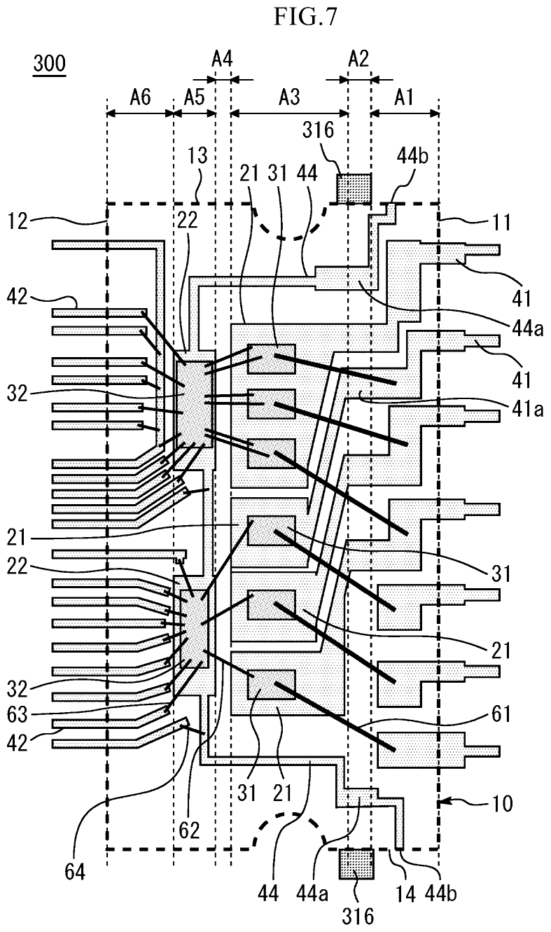

FIG. 7 is a plan view of a semiconductor device 300 according to the fourth embodiment. In this embodiment, an injection portion 316 for the sealing resin that constitutes the package 10 is provided at a position of the package 10 closer to the first side 11 than to the second side 12. The injection portion 316 is provided as an injection mark of the sealing material in the package 10. The implantation portion 316 is formed in, for example, the region A2.

If a metal wire thinner than the power wire 61 is used as the control wire 63 or the wire 62, the injection pressure when injecting a sealing material such as resin into the package 10 may cause the wire to bend and come into contact with a different electrode. In particular, when the control chip 32 is provided at a position lower than the control terminals 42, the control wires 63 must be extended from the control chip 32 to the control terminals 42, which may cause the control wires 63 to easily drift. In this embodiment, the position where the sealing material is injected is on the first side 11 side, so that the effect of the injection pressure on the control wire 63 can be reduced. Therefore, the wire sweep can be suppressed.

The technical features described in each embodiment may be used in appropriate combination.

Hereinafter, various aspects of the present disclosure will be collectively described as appendixes.

### Appendix 1

A semiconductor device comprising:
a package having a first side and a second side opposite the first side;
a conductor layer having a first region provided inside the package and a second region provided inside the package between the first region and the second side;
a semiconductor chip provided on the first region;
a control chip provided on the second region and configured to control the semiconductor chip;
a power terminal provided on the first side of the package and electrically connected to the semiconductor chip;
a control terminal provided on the second side of the package and electrically connected to the control chip; and
a suspension lead extending from a position on an outer periphery of the package closer to the first side than the first region to the second region; wherein
a first step portion is formed in the suspension lead such that a portion connected to the second region is lower than a portion provided in the outer periphery; and
the second region is provided at a position lower than a portion of the control terminal that is provided inside the package.

### Appendix 2

The semiconductor device according to appendix 1, wherein the first step portion is formed closer to the first side than the first region.

### Appendix 3

The semiconductor device according to appendix 1 or 2, wherein the power terminal has a second step portion formed inside the package, and
the first step portion and the second step portion are formed at the same position in a direction from the first side toward the second side.

### Appendix 4

The semiconductor device according to any one of appendixes 1 to 3, wherein a pair of the suspension leads are provided on both sides of the package.

### Appendix 5

The semiconductor device according to any one of appendixes 1 to 4, wherein the first region and the second region are provided at a same height.

### Appendix 6

The semiconductor device according to any one of appendixes 1 to 5, wherein the package is formed of a sealing resin,
an insulating sheet or an insulating substrate is provided directly below the first region inside the package; and
only the sealing resin is provided directly below the second region inside the package.

### Appendix 7

The semiconductor device according to any one of appendixes 1 to 5, wherein an insulating sheet or an insulating substrate is provided directly below the first region and the second region.

### Appendix 8

The semiconductor device according to any one of appendixes 1 to 7, wherein a dielectric constant of a member directly below the control chip is lower than a dielectric constant of a member directly below the semiconductor chip.

### Appendix 9

The semiconductor device according to any one of appendixes 1 to 8, wherein a diameter of a control wire connecting the control chip and the control terminal is smaller than a diameter of a power wire connecting the semiconductor chip and the power terminal.

### Appendix 10

The semiconductor device according to any one of appendixes 1 to 9, wherein the package is formed of a sealing resin, and
an injection portion for the sealing resin is provided at a position closer to the first side of the package than to the second side.

### Appendix 11

The semiconductor device according to any one of appendixes 1 to 10, wherein the control chip is provided with a bootstrap diode or a regulator.

### Appendix 12

The semiconductor device according to any one of appendixes 1 to 11, wherein the semiconductor chip is made with a wide bandgap semiconductor.

### Appendix 13

The semiconductor device according to claim 12, wherein the wide band gap semiconductor is silicon carbide, gallium nitride-based material, or diamond.

In the semiconductor device according to the present disclosure, the step portion is formed in the suspension lead that extends from a position closer to the first side than the first region to the second region. Therefore, in order to arrange the second region at a lower position within the package, it is not necessary to bend the leads on the second side inside the package. Therefore, the space inside the package can be reduced.

Obviously many modifications and variations of the present disclosure are possible in the light of the above teachings. It is therefore to be understood that within the scope of the appended claims the disclosure may be practiced otherwise than as specifically described.

The entire disclosure of a Japanese Patent Application No. 2024-216950, filed on Dec. 11, 2024 including specification, claims, drawings and summary, on which the Convention priority of the present application is based, are incorporated herein by reference in its entirety.

1. A semiconductor device comprising:
a package having a first side and a second side opposite the first side;
a conductor layer having a first region provided inside the package and a second region provided inside the package between the first region and the second side;
a semiconductor chip provided on the first region;
a control chip provided on the second region and configured to control the semiconductor chip;
a power terminal provided on the first side of the package and electrically connected to the semiconductor chip;
a control terminal provided on the second side of the package and electrically connected to the control chip; and
a suspension lead extending from a position on an outer periphery of the package closer to the first side than the first region to the second region; wherein a first step portion is formed in the suspension lead such that a portion connected to the second region is lower than a portion provided in the outer periphery; and
the second region is provided at a position lower than a portion of the control terminal that is provided inside the package.

2. The semiconductor device according to claim 1, wherein the first step portion is formed closer to the first side than the first region.

3. The semiconductor device according to claim 1, wherein the power terminal has a second step portion formed inside the package, and
the first step portion and the second step portion are formed at the same position in a direction from the first side toward the second side.

4. The semiconductor device according to claim 1, wherein a pair of the suspension leads are provided on both sides of the package.

5. The semiconductor device according to claim 1, wherein the first region and the second region are provided at a same height.

6. The semiconductor device according to claim 1, wherein the package is formed of a sealing resin,
an insulating sheet or an insulating substrate is provided directly below the first region inside the package; and
only the sealing resin is provided directly below the second region inside the package.

7. The semiconductor device according to claim 1, wherein an insulating sheet or an insulating substrate is provided directly below the first region and the second region.

8. The semiconductor device according to claim 1, wherein a dielectric constant of a member directly below the control chip is lower than a dielectric constant of a member directly below the semiconductor chip.

9. The semiconductor device according to claim 1, wherein a diameter of a control wire connecting the control chip and the control terminal is smaller than a diameter of a power wire connecting the semiconductor chip and the power terminal.

10. The semiconductor device according to claim 1, wherein the package is formed of a sealing resin, and
an injection portion for the sealing resin is provided at a position closer to the first side of the package than to the second side.

11. The semiconductor device according to claim 1, wherein the control chip is provided with a bootstrap diode or a regulator.

12. The semiconductor device according to claim 1, wherein the semiconductor chip is made with a wide bandgap semiconductor.

13. The semiconductor device according to claim 12, wherein the wide band gap semiconductor is silicon carbide, gallium nitride-based material, or diamond.
